(19) United States
(12) Patent Application Publication
(10) Pub. No.: US 2015/0082616 A1
(43) Pub. Date: Mar. 26, 2015

(54) METHOD FOR SELECTING OPTIMAL MANUFACTURING PROCESS FOR PRODUCING PRINTED CIRCUIT BOARDS

(71) Applicant: Avago Technologies General IP (Singapore) Pte. Ltd., Singapore (SG)

(72) Inventors: Jin Jeong, Kyunggi province (KR); Chris Chung, Seoul (KR); Tae Eun Kim, Bucheon-si (KR)

(73) Assignee: Avago Technologies General IP (Singapore) Pte. Ltd., Singapore (SG)

(21) Appl. No.: 14/038,587

(22) Filed: Sep. 26, 2013

(51) Int. Cl. H05K 3/00

(52) U.S. Cl. CPC H05K 3/00
USPC 29/593

(57) ABSTRACT

A method is provided for selecting an optimal manufacturing process for producing printed circuit boards. The method includes measuring electrical characteristics of a reference printed circuit board having circuitry; producing two or more printed circuit boards using two or more candidate manufacturing processes, respectively, each produced printed circuit board having circuitry that is the same as the circuitry of the reference printed circuit board; measuring electrical characteristics of each of the produced printed circuit boards; and selecting a candidate manufacturing process of the two or more candidate manufacturing processes based on the measured electrical characteristics of the reference printed circuit board.

### BACKGROUND

Printed circuit boards (PCBs) are widely used for incorporating various circuits including radio frequency (RF) circuits, microwave circuits, and the like. Generally, PCBs are manufactured by forming a conductor pattern or circuitry on the surface of a dielectric material using various pattern forming techniques, such as etching, printing, and the like.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. Where technical features in the figures, detailed description or any claim are followed by references signs, the reference signs have been included for the sole purpose of increasing the intelligibility of the figures, detailed description, and/or claims. Accordingly, neither the reference signs nor their absence are intended to have any limiting effect on the scope of any claim elements. In the figures, each identical or nearly identical component that is illustrated in various figures is represented by a like numeral. For purposes of clarity, not every component may be labeled in every figure. In the figures:

FIG. 1A shows transmission lines and a via formed in a printed circuit board (PCB);

FIG. 1B shows an equivalent circuit for the transmission lines of FIG. 1A;

FIG. 2A illustrates a misalignment of transmission lines;

FIG. 2B illustrates an occurrence of a parasitic capacitance due to a misalignment of transmission lines;

FIG. 3A illustrates a misalignment of a via;

FIG. 3B illustrates occurrence of a parasitic capacitance due to misalignment of a via;

FIG. 4 shows a reference PCB, in accordance with a representative embodiment;

FIG. 5 shows a reference PCB in accordance with a representative embodiment;

FIG. 6 is an exaggerated view of a distance measurement structure shown in FIG. 5, in accordance with a representative embodiment;

FIG. 7 is a flow chart of a method for determining an optimal process for manufacturing PCB, in accordance with a representative embodiment;

FIG. 8 is a plot of S21 parameters measured for a reference PCB and PCBs produced by candidate manufacturing processes, in accordance with a representative embodiment;

FIG. 9 shows a relationship between S21 parameter and yield rates for PCBs produced by candidate manufacturing processes, in accordance with a representative embodiment; and

FIG. 10 shows a relationship between via-GND distance and yield rates for PCBs produced by candidate manufacturing processes, in accordance with a representative embodiment.

### DETAILED DESCRIPTION

In the following detailed description, for purposes of explanation and not limitation, specific details are set forth in order to provide a thorough understanding of illustrative embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the illustrative embodiments. Such methods and apparatuses are clearly within the scope of the present teachings.

Representative embodiments are generally directed to methods of fabricating a cavity in a printed circuit board (PCB) that exposes the PCB circuitry for a package, such as flip-chip or die-attach assembly of semi-conductors, for example. The cavity has metal plated (e.g., copper plated) side and bottom surfaces, which may provide electromagnetic interference (EMI) from adjacent circuitry and a more robust electrical design solution. In addition, the construction of the cavity enables reduced thermal resistance to the bottom interface. Also, placement of components (e.g., dies) within the cavity reduces overmold thickness, and thus overall package thickness. The reduced overmold thickness also reduces overmold-induced stresses that may otherwise reduce die interconnect reliability and/or cause package warpage, particularly with thin PCB substrates, for example.

It is to be appreciated that embodiments of the methods and apparatuses discussed herein are not limited in application to the details of construction and the arrangement of components set forth in the following description or illustrated in the accompanying figures. The methods and apparatuses are capable of implementation in other embodiments and of being practiced or of being carried out in various ways. Examples of specific implementations are provided herein for illustrative purposes only and are not intended to be limiting. In particular, acts, elements and features discussed in connection with any one or more embodiments are not intended to be excluded from a similar role in any other embodiments. Like reference numerals in the figures refer to like elements.

Also, the phraseology and terminology used herein is for the purpose of description and should not be regarded as limiting. Any references to embodiments or elements or acts of the systems and methods herein referred to in the singular may also embrace embodiments including a plurality of these elements, and any references in plural to any embodiment or element or act herein may also embrace embodiments including only a single element. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Any references to front and back, left and right, top and bottom, and upper and lower are intended for convenience of description, not to limit the present systems and methods or their components to any one positional or spatial orientation. The terms “a” or “an”, as used herein are defined as one or more than one. The term “plurality” as used herein is defined as two or more than two.

As used in the specification and appended claims, and in addition to their ordinary meanings, the terms “substantial” or “substantially” mean to with acceptable limits or degree. Also, as used in the specification and the appended claims and in addition to its ordinary meaning, the terms “about” and “approximately” mean to within an acceptable limit or amount to one having ordinary skill in the art. For example, “approximately the same” means that one of ordinary skill in the art would consider the items being compared to be the same.

Various embodiments provide a reference PCB with desired electrical characteristics and a method for determining an optimal process for manufacturing PCBs, selected from among multiple possible manufacturing processes, based on the electrical characteristics of the reference PCB. The optimal manufacturing process is the manufacturing process that is best or most desirable from the perspective of producing PCBs having electrical characteristics that most nearly match the electrical characteristics of the reference PCB. The optimal manufacturing process may provide minimum processing error. For example, the optimal manufacturing process may produce PCBs such that misalignments in transmission lines and/or a vias (and corresponding effects on electrical characteristics) are minimized.

In accordance with an embodiment, there is provided a method for selecting an optimal manufacturing process for producing printed circuit boards. The method includes measuring electrical characteristics of a reference printed circuit board having circuitry; producing two or more printed circuit boards using two or more candidate manufacturing processes, respectively, each produced printed circuit board having circuitry that is the same as the circuitry of the reference printed circuit board; measuring electrical characteristics of each of the produced printed circuit boards; and selecting a candidate manufacturing process of the two or more candidate manufacturing processes based on the measured electrical characteristics of the reference printed circuit board.

In accordance with another aspect of the invention, there is provided a method for selecting an optimal process for manufacturing printed circuit boards. The method includes producing multiple printed circuit boards using multiple candidate manufacturing processes, respectively, each produced printed circuit board having circuitry that is the same as circuitry of a reference printed circuit board; measuring electrical characteristics of each of the produced printed circuit boards; determining which produced printed circuit board has measured electrical characteristics closest to corresponding electrical characteristics of the reference printed circuit board; and selecting the candidate manufacturing process corresponding to the determined printed circuit board to be the optimal manufacturing process. The selected candidate manufacturing process is then used for production of printed circuit board product.

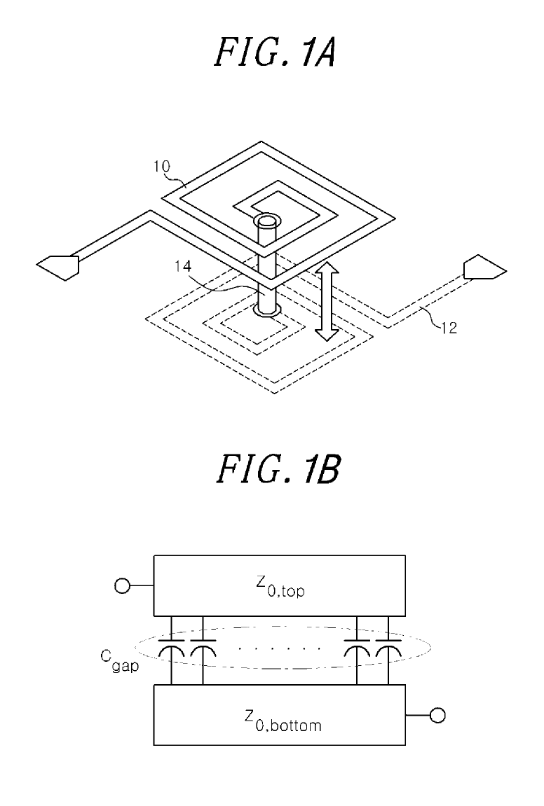

FIG. 1A shows a PCB with conductive transmission lines and a via. In particular, upper transmission line 10 and lower transmission line 12 are formed on different layers and connected to each other through via 14. The structure depicted n FIG. 1A may be implemented in multiple ways. For example, the upper transmission line 10 may be formed on a top surface of a dielectric material, while the lower transmission line 12 may be formed on a bottom surface of the dielectric material. Alternatively, the upper and lower transmission lines 10, 12 may be formed on different layers of dielectric materials, and the dielectric material layers are then laminated. The via 14 is a hole passing through the dielectric material, and the inner surface of the via 14 is covered or coated with a conductive material to connect the upper and lower transmission lines 10, 12.

For high frequency signals, such as RF signals and microwave signals, the upper and lower transmission lines 10, 12 act as impedance (i.e., series resistance and inductance). Due to the electromagnetic coupling between the upper and lower transmission lines 10, 12, capacitance may also be induced. FIG. 1B shows an equivalent circuit model of the transmission lines of FIG. 1A, in which the upper transmission line 10 and the lower transmission line 12 are represented by top impedance Z_{0,top} and bottom Z_{0,bottom}, respectively, and the capacitance between the upper transmission line 10 and the lower transmission line 12 is represented by equivalent capacitor Cgap. As shown in FIG. 1B, a capacitance may be induced by two conductors separated by the gap. However, if the two conductors are misaligned, it may cause unexpected or undesirable capacitance, which may be referred to as a parasitic capacitance, as explained in more detail, below.

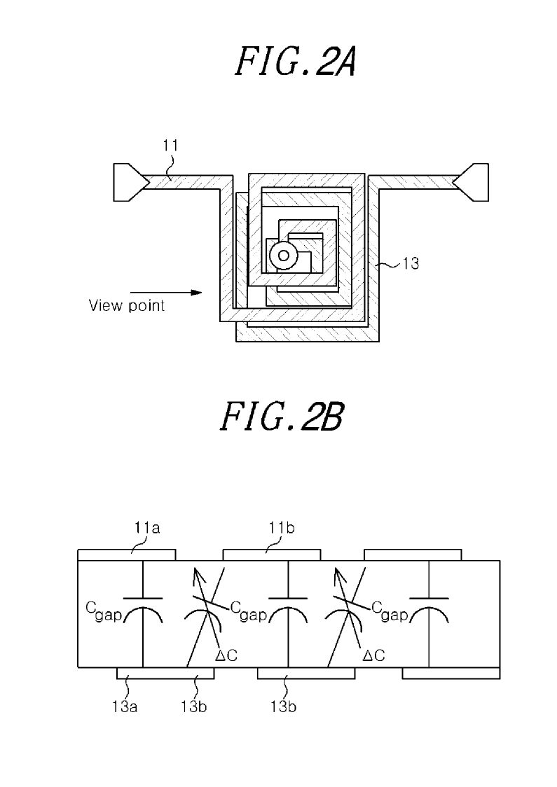

FIG. 2A shows a PCB with misaligned transmission lines and a via, and FIG. 2B is a cross-sectional view of FIG. 2A that shows inducement of parasitic capacitance. The upper and lower lines 11, 13 shown in FIG. 2A are similar to the upper and lower transmission lines 10, 12 in FIG. 1A, respectively, except that the upper and lower lines 11, 13 are misaligned, e.g., due to error occurring during the manufacturing process. FIG. 2A shows parts 11a and 11b of the upper line 11, and parts 13a and 13b of the lower line 13. Capacitance Cgap is induced by parts 11a, 13a, which are intended to be aligned with each other. As a result of the misalignment, parasitic capacitance AC is also induced by parts 11b, 13b, which unintentionally overlap each other. This parasitic capacitance induced by the misalignment of the upper and lower lines 11, 13 may result in electrical characteristics of the circuit that deviate from those intended.

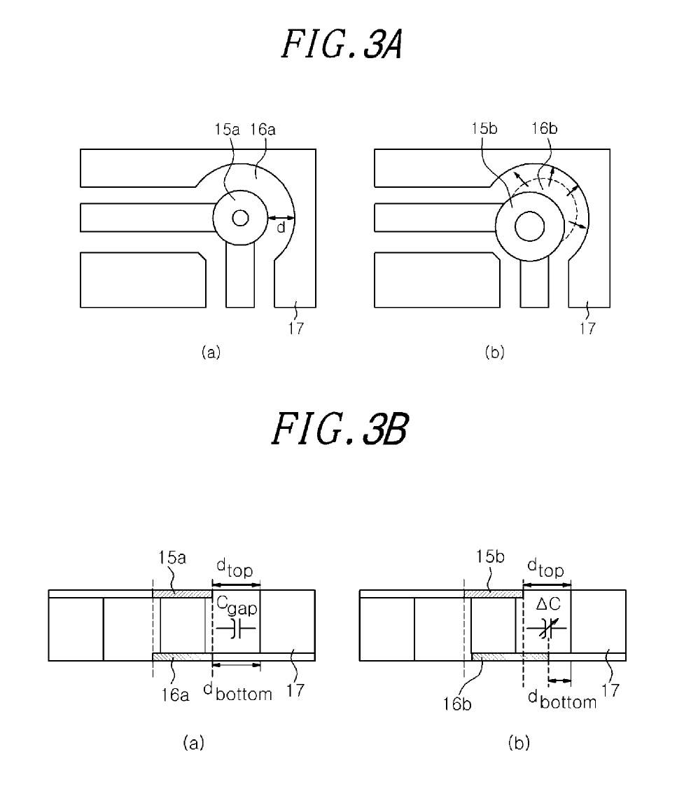

Another factor that results in deviation in electrical characteristics may occur in the via 14, as illustrated in FIG. 3A. FIG. 3A(a) shows the intended structure of the via, in which the top conductor 15a and the bottom conductor 16a are well aligned and separated from a neighboring ground conductor 17 by a preset distance d. In contrast, in the via shown in FIG. 3A(b), top conductor 15b is misaligned with bottom conductor 16b, such that the bottom conductor 16b is closer to the ground conductor 17 than the top conductor 15b. As used hereinafter, the term “via-GND distance” refers to a distance between the via 14 and the ground conductor 17.

FIG. 3B is a cross-sectional view of FIG. 3A that shows inducement of parasitic capacitance due to the misalignment of the via. In particular, FIG. 3B(a) shows a cross-sectional view of FIG. 3A(a). In FIG. 3B(a), the distance dtop between the top conductor 15a and the ground conductor 17 is the same as the distance dbottom between the bottom conductor 16a and the ground conductor 17. The capacitance Cgap is induced between the via 14 and the ground conductor 17. FIG. 3B(b) shows a cross-sectional view of FIG. 3A(b). In FIG. 3B(b), the distance dtop between the top conductor 15b and the ground conductor 17 is larger than the distance dbottom between the bottom conductor 16b and the ground conductor 17, due to misalignment. The capacitance induced between the via 14 and the ground conductor 17 is AC.

As described above, misalignment of transmission lines and/or a via may influence the circuit capacitance, and in turn, may cause non-optimal deviations or changes in the electrical characteristics of the circuit from those intended. Particularly, when the frequency of a signal is high, a small change in the capacitance may result in a relatively large deviation in electrical characteristics. Accordingly, it is desirable to suppress and/or control misalignments of the transmission lines and/or vias during the course of manufacturing PCBs. This may be accomplished by selecting an optimal manufacturing process from among multiple possible manufacturing processes.

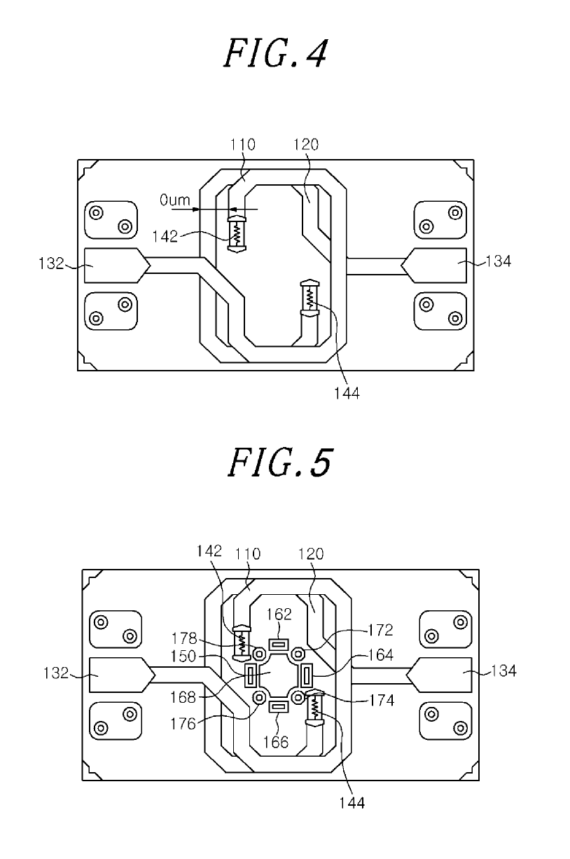

FIG. 4 shows a reference PCB, in accordance with a representative embodiment. The reference PCB of the depicted embodiment has a first surface and a second surface on which transmission lines may be formed. The first and second surfaces may be the top and bottom surfaces of the PCB, respectively. Alternatively or additionally, when a reference PCB is a multilayered PCB, the first and second surfaces may be a top surface or a bottom surface of boards at different layers.

Referring to FIG. 4, a first transmission line 110 is formed on the first surface and a second transmission line 120 is formed on the second surface. In the reference PCB, the first transmission line 110 and the second line 120 are substantially aligned with each other, without error, such that parasitic capacitance (e.g., ΔC in FIG. 2B) is not created and the circuit has intended electrical characteristics.

One end of the first transmission line 110 is connected to a signal pad 132 and the other end is connected to termination impedance 142. Similarly, one end of the second transmission line 120 is connected to a signal pad 134 and the other end is connected to termination impedance 144. The signal pads 132, 134 may be used for measuring electrical characteristics, such as the S-parameters (e.g., S21 parameter) of the first and second transmission lines 110, 120. The termination impedances 142, 144 are provided for impedance matching for the first and second transmission lines 110, 120, respectively.

According to a representative embodiment, the dimensions of the reference PCB may be about 15.00 nm (W) by about 5.00 mm (L), for example, although other dimensions may be incorporated without departing from the scope of the present teachings.

The reference PCB shown in FIG. 4 with the first and second transmission lines 110, 120 may be used as a reference for determining alignment of transmission lines of other PCBs, although it cannot be used as a reference for determining an alignment of vias. FIG. 5 shows a reference PCB, in accordance with a representative embodiment, which can be used as a reference for alignment of a via. The PCB shown in FIG. 5 is substantially the same as the PCB shown in FIG. 4, except that it further includes a distance measurement structure having one or more vias, indicated by representative vias 162, 164, 166, 168, 172, 174, 176 and 178, and a conductor 150 formed on the first surface of the PCB.

The conductor 150 and the vias 162 to 178 may be placed in an area where the first and second transmission lines 110, 120 are not formed, such as a center portion of the PCB, for example, and separated from the lines 110 and 120. Accordingly, the addition of the conductor 150 and the vias 162 to 178 do not alter the electrical characteristics of the first and second transmission lines 110, 120.

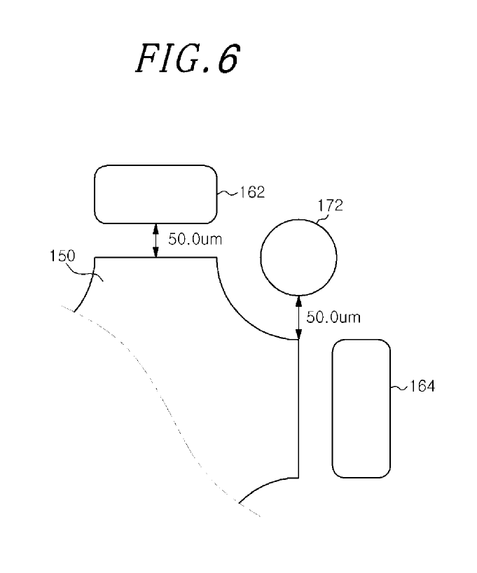

For the reference PCB, the distance between an outer perimeter of each of the vias 162 to 178 and the conductor 150, also referred to a via-GND distance, is a preset distance. FIG. 6 shows an exaggerated view of the distance measurement structure shown in FIG. 5, in which the representative via-GND distances (i.e., the distance between the via 162 and a conductor 150 and the distance between the via 172 and the conductor 150) may be 50 μm, for example, although other via-GND distances may be incorporated without departing from the scope of the present teachings.

In various embodiments, the reference PCB may include one or more rectangular-shaped vias 162, 164, 166 and 168 and/or one or more circular-shaped vias 172, 174, 176 and 178. Because a rectangular-shaped via and a circular-shaped via may be treated differently during the manufacturing process and may be subject to different processing errors, they are both formed in the reference PCB to be considered in determining the optimal manufacturing process.

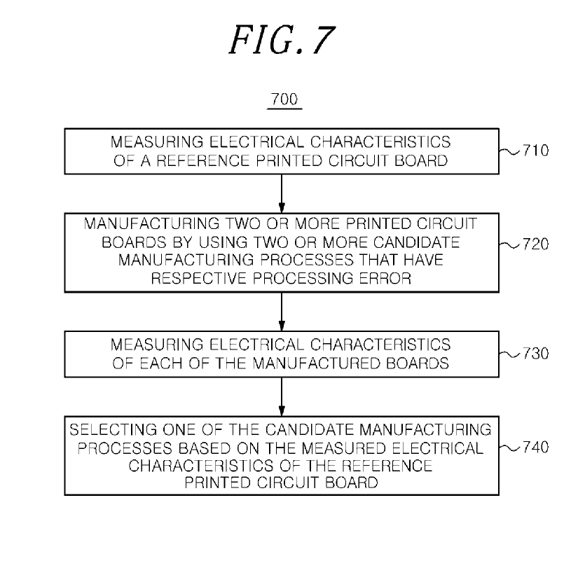

FIG. 7 is a flow chart of a method for determining an optimal manufacturing process for manufacturing a PCB, in accordance with a representative embodiment, for example, using a reference PCB, discussed above.

In method 700, initially electrical characteristics of a reference PCB are measured in step 710. The reference PCB has circuitry that is produced to have substantially no misalignment between transmission lines (e.g., first and second transmission lines 110, 120) and/or between vias and a conductor (e.g., vias 162 to 178 and conductor 150), such as the illustrative reference PCBs discussed above with reference to FIG. 4 and/or FIG. 5, for example.

The electrical characteristics may include S21 parameters and/or via-GND distances, for example, as discussed above. In various embodiments, measuring the electrical characteristics includes measuring the S21 parameters using signal pads (e.g., the signal pads 132, 134 in FIG. 4 or FIG. 5). For example, the S21 parameters may be measured using a network analyzer connected to the signal pads 132, 134. Alternatively or additionally, measuring the electrical characteristics includes measuring the via-GND distances using a camera. In an embodiment, a digital camera placed beyond the conductor 150 and the vias 162 to 178 (FIG. 5) may be used to measure the via-GND distances, for example.

In step 720, two or more PCBs are produced using two or more candidate manufacturing processes, respectively, which have respective processing errors. Each produced PCB has circuitry that is the same as the circuitry of the reference PCB. Although the produced PCBs have circuitry that is substantially the same as that of the reference PCB as shown in FIG. 4 or FIG. 5, they are subject to processing errors of corresponding candidate manufacturing process, such that the resultant PCBs may have different amounts of misalignment of transmission lines and/or vias. Although step 720 is described as being carried out after step 710, step 720 may be carried out before or simultaneously with step 710, without departing from the scope of the present teachings.

Next, in step 730, electrical characteristics of each of the produced PCBs are measured. In an embodiment, multiple PCBs may be produced using each of the candidate manufacturing processes. In this case, one PCB may be selected as representative of the multiple PCBs produced using each of the candidate manufacturing processes for measuring electrical characteristics in step 730. However, more than one PCB (or all of the PCBs) produced from each candidate manufacturing process may be used for measuring the electrical characteristics of PCBs produced using each of the candidate manufacturing processes. Measuring the electrical characteristics in step 730 may be performed in substantially the same manner as described above with reference to step 710. For example, the electrical characteristics may include S21 parameters and/or via-GND distances. In one embodiment, measuring the electrical characteristics includes measuring S21 parameters using the signal pads (like signal pads 132, 134 in FIG. 4 or FIG. 5). For example, the S21 parameters may be measured with a network analyzer connected to the signal pads. Alternatively or additionally, measuring the electrical characteristics may include measuring with a camera via-GND distances. In an embodiment, a digital camera may be placed beyond the conductor and the vias (like conductor 150 and vias 162 to 178 in FIG. 5) and used to measure the via-GND distances.

In step 740, a candidate manufacturing process of the two or more candidate manufacturing processes is selected as the optimal manufacturing process based on the measured electrical characteristics of the reference PCB. For example, the optimal manufacturing process may be determined by comparing the measured electrical characteristics of the PCBs produced by each corresponding candidate manufacturing process (step 730) with the corresponding measured electrical characteristics of the reference PCB (step 710). The candidate manufacturing process that produces the PCB(s) having measured electrical characteristics closest to the measured characteristics of the reference PCB is determined to be the optimal manufacturing process, and thus selected. The selected candidate manufacturing process is then used for manufacturing product PCBs.

In various embodiments, determining which candidate manufacturing process is to be selected as the optimal manufacturing process may include producing a lot or a batch of products using each of the candidate manufacturing processes. When a lot or a batch of products has been produced by each of the candidate manufacturing processes, selecting which candidate manufacturing process is the optimal manufacturing process may result in using the corresponding lot or batch of PCBs produced by that manufacturing process. However, producing actual products by multiple candidate manufacturing processes, only one of which may ultimately be selected, results in waste of the unselected lots or batches of PCBs. Therefore, it may be desirable to determine the optimal manufacturing process before manufacturing a significant amount of products in order to reduce costs.

According to an embodiment, it is possible to determine an optimal manufacturing process by producing PCBs having relatively simple structure (e.g., corresponding to the reference PCB) at relatively low cost. This allows for cost savings that would not have been incurred by choosing a non-optimal manufacturing process and making products that are subsequently discovered to be faulty. Notably, the cost of producing reference PCBs, e.g., as shown in FIGS. 4 and 5, is generally much lower than the cost of manufacturing actual products, which typically have complex transmission lines and/or via arrangements.

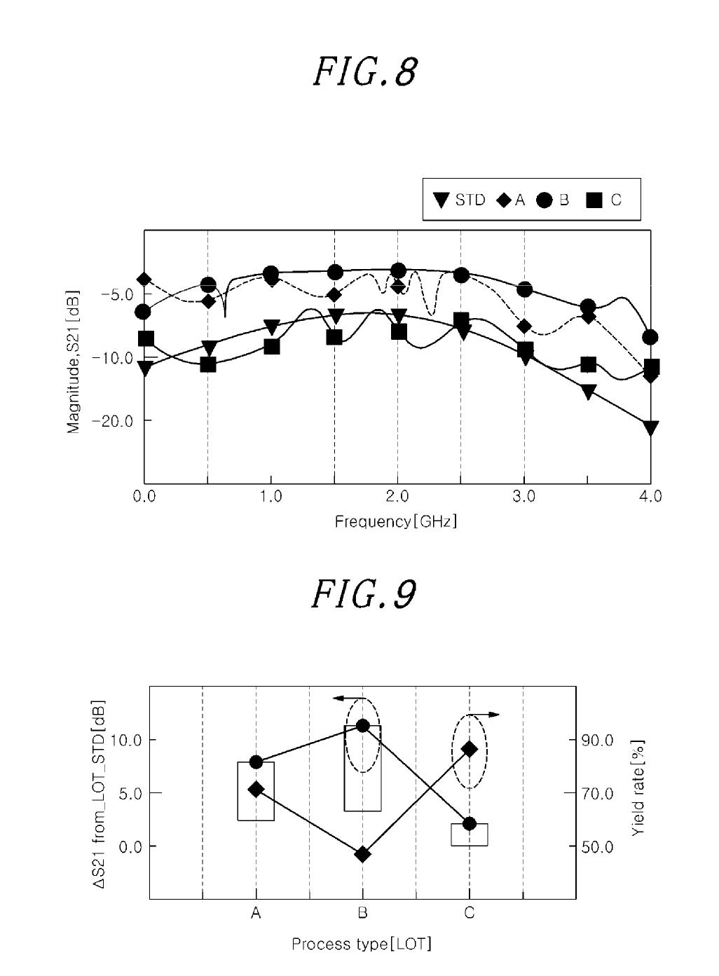

FIG. 8 is a plot of S21 parameters measured for a reference PCB and PCBs produced by different candidate manufacturing processes, in accordance with a representative embodiment. In FIG. 8, line STD represents the S21 parameter of the reference PCB, and lines A, B and C represent the S21 parameters of the PCBs produced by candidate manufacturing processes A, B and C, respectively. As can be seen from FIG. 8, the PCB produced by the candidate manufacturing process C has the S21 parameter closest to that of the reference PCB, indicating that manufacturing process C would be selected as the optimal manufacturing process.

To verify that the candidate manufacturing process C is actually the optimal manufacturing process, the relationship between the S21 parameters and yield rates for PCBs produced by the candidate manufacturing processes are measured, as shown in FIG. 9. In FIG. 9, squares represent yield rates for each of the candidate manufacturing processes, while circles represent the difference in S21 parameters ΔS21 between the PCBs produced by each candidate manufacturing process and the reference PCB. As shown, for the candidate manufacturing process C, ΔS21 is the lowest, while the yield rate is the highest. Comparing with ΔS21 and yield rates for the candidate manufacturing processes A and B, it can be confirmed that the candidate manufacturing process C is the optimal manufacturing process based on ΔS21.

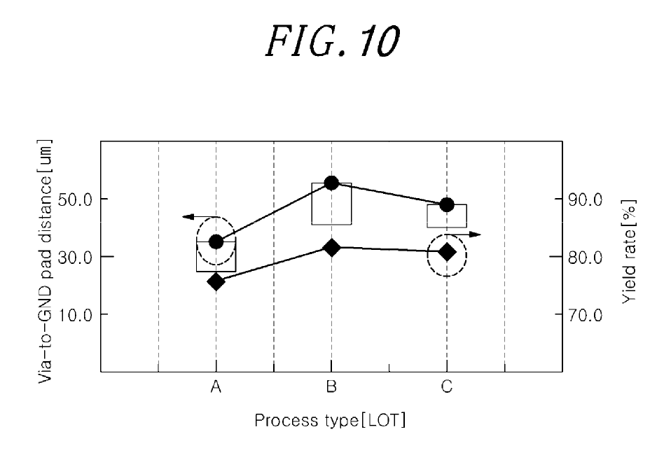

FIG. 10 shows relationships between via-GND distances and yield rates for PCBs produced by candidate manufacturing processes. In FIG. 10, squares represent yield rates of each candidate manufacturing process, while circles represent via-GND distances of the PCBs produced by each candidate manufacturing process. As shown in FIG. 10, the yield rate of a candidate manufacturing process is higher when the via-GND distance of the PCB produced by the candidate manufacturing process is closer to that of the reference PCB (e.g., 50 μm in this example). Accordingly, it is possible to determine an optimal manufacturing process based on the via-GND distances.

Having thus described several aspects of at least a representative embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A method for selecting an optimal manufacturing process for producing printed circuit boards, the method comprising:
measuring electrical characteristics of a reference printed circuit board having circuitry;
producing a two or more printed circuit boards using two or more candidate manufacturing processes, respectively, each produced printed circuit board having circuitry that is the same as the circuitry of the reference printed circuit board;
measuring electrical characteristics of each of the produced printed circuit boards; and
selecting a candidate manufacturing process of the two or more candidate manufacturing processes based on the measured electrical characteristics of the reference printed circuit board.

2. The method of claim 1, wherein the measured electrical characteristics of the printed circuit board produced using the selected candidate manufacturing process are the closest to the measured electrical characteristics of the reference printed circuit board.

3. The method of claim 1, wherein the reference printed circuit board comprises:
a first surface;
a second surface;
a first transmission line formed on the first surface; and
a second transmission line formed on the second surface,
wherein the first and the second transmission lines of the reference printed circuit board are substantially aligned with each other.

4. The method of claim 3, wherein one end of each of the first and the second transmission lines is connected to a signal pad, and the other end of each of the first and the second transmission lines is connected to a termination impedance.

5. The method of claim 3, wherein the reference printed circuit board further comprises:
a conductor formed on the first surface; and
one or more vias.

6. The method of claim 5, wherein the one or more vias comprise at least one rectangular-shaped via and at least one circular-shaped via.

7. The method of claim 1, wherein measuring electrical characteristics of each of the produced printed circuit boards comprises:
measuring a distance between an outer perimeter of a via and a conductor in each of the produced printed circuit boards.

8. The method of claim 7, wherein the distance between the outer perimeter of the via and the conductor is measured using a camera.

9. The method of claim 1, wherein measuring electrical characteristics of each of the produced printed circuit boards comprises:
measuring S21 parameters of transmission lines on each of the produced printed circuit boards.

10. The method of claim 9, wherein the S21 parameters of the transmission lines are measured using a network analyzer connected to signal pads connected to the transmission lines, respectively.

11. The method of claim 1, wherein each of the two more candidate manufacturing processes have corresponding processing errors.

12. A method for selecting an optimal process for manufacturing printed circuit boards, the method comprising:
producing a plurality of printed circuit boards using a plurality of candidate manufacturing processes, respectively, each produced printed circuit board having circuitry that is the same as circuitry of a reference printed circuit board;
measuring electrical characteristics of each of the produced printed circuit boards;
determining which produced printed circuit board has measured electrical characteristics closest to corresponding electrical characteristics of the reference printed circuit board; and
selecting the candidate manufacturing process corresponding to the determined printed circuit board to be the optimal manufacturing process.

13. The method of claim 12, wherein the reference printed circuit board comprises:
a first surface;
a second surface;
a first transmission line formed on the first surface; and
a second transmission line formed on the second surface,
wherein the first and the second transmission lines are substantially aligned with each other.

14. The method of claim 13, wherein one end of each of the first and the second transmission lines is connected to a signal pad, and the other end of each of the first and the second transmission lines is connected to a termination impedance.

15. The method of claim 13, wherein the reference printed circuit board further comprises:
a conductor formed on the first surface; and
a via, wherein a distance between an outer perimeter of the via and the conductor is a preset distance.

16. The method of claim 15, wherein the via comprises one of a rectangular-shaped via and a circular-shaped via.

17. The method of claim 12, wherein measuring the electrical characteristics of each of the produced printed circuit boards comprises:
measuring S-parameters of transmission lines on each of the produced printed circuit boards.

18. The method of claim 17, wherein measuring the electrical characteristics of each of the produced printed circuit boards further comprises:
measuring a distance between an outer perimeter of the via and the conductor in each of the produced printed circuit boards.
